(19) United States
(12) Patent Application Publication
(10) Pub. No.: US 2012/0183805 A1
(43) Pub. Date: Jul. 19, 2012

(54) COATED ARTICLE AND METHOD FOR MAKING THE SAME

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); ZI-CHENG WAN, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD ., Shenzhen City (CN)

(21) Appl. No.: 13/233,847

(22) Filed: Sep. 15, 2011

(30) Foreign Application Priority Data
Jan. 18, 2011 (CN) 201110020635.4

(51) Int. Cl. B32B 15/20; C23C 14/35; C23C 14/16; B32B 15/04; C23C 14/08

(52) U.S. Cl. 428/632; 204/192.15

(57) ABSTRACT

A coated article includes a substrate and a color layer formed on the substrate. The substrate is made of aluminum or aluminum alloy. The color layer includes an aluminum layer formed on the substrate and an aluminum oxide layer formed on the aluminum layer. In the CIE LAB color system, L* coordinate of the color layer is between 75 and 100, a* coordinate of the color layer is between −1 and 1, b* coordinate of the color layer is between −1 and 1. The coated article has a white color.

### BACKGROUND

1. Technical Field

The present disclosure relates to coated articles and a method for making the coated articles.

2. Description of Related Art

To make housings for electronic devices having a pleasing appearance, the typical method is to make a colored plastic housing or to paint the electronic devices with colored layers. However, the plastic housing and the painted housing can not present good metallic textures. To present good metallic textures, the housings can be coated by vacuum deposition. However, the vacuum deposition technology can be complex and difficult to control, further the types of colors for the coatings made by vacuum deposition technology are not rich.

Therefore, there is room for improvement within the art.

### BRIEF DESCRIPTION OF THE FIGURE

Many aspects of the coated article and the method for making the coated article can be better understood with reference to the following drawings. The components in the drawings are not necessarily drawn to scale, the emphasis instead being placed upon clearly illustrating the principles of the coated article and the method. Moreover, in the drawings like reference numerals designate corresponding parts throughout the several views. Wherever possible, the same reference numbers are used throughout the drawings to refer to the same or like elements of an embodiment.

FIG. 1 is a cross-sectional view of an exemplary coated article;

FIG. 2 is a schematic view of a vacuum sputtering device for fabricating the coated article in FIG. 1.

### DETAILED DESCRIPTION

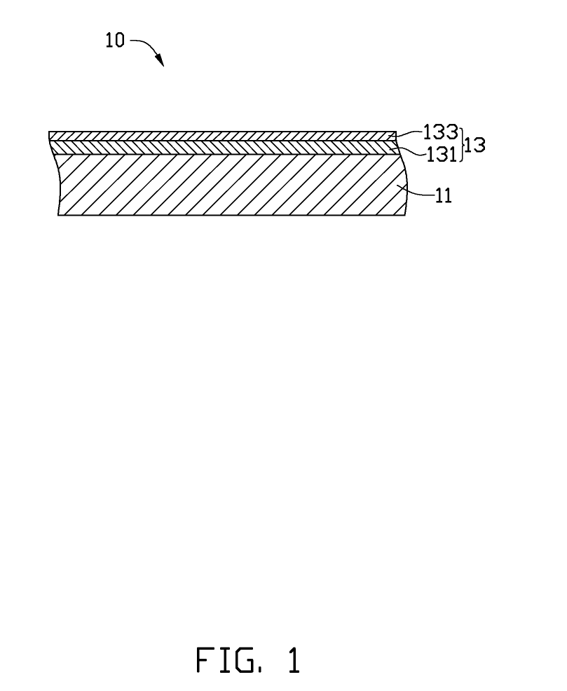

FIG. 1 shows a coated article 10 according to an exemplary embodiment. The coated article 10 includes a substrate 11 and a color layer 13 formed on the substrate 11. The coated article 10 may be used as a housing for a computer, communication device, or a consumer electronic device.

The substrate 11 is made of aluminum or aluminum alloy.

The color layer 13 includes an aluminum layer 131 formed on the substrate 11 and an aluminum oxide layer 133 formed on the aluminum layer 131. The aluminum layer 131 has a thickness of about 1.0 μm to about 3.0 μm. The aluminum oxide layer 133 has a thickness of about 0.5 μm to about 1.0 μm. A vacuum sputtering process may be used to form the color layer 13. The color layer 13 has a white color. In the CIE LAB color system, L* coordinate is between 75 and 100, a* coordinate is between −1 and 1, b* coordinate is between −1 and 1.

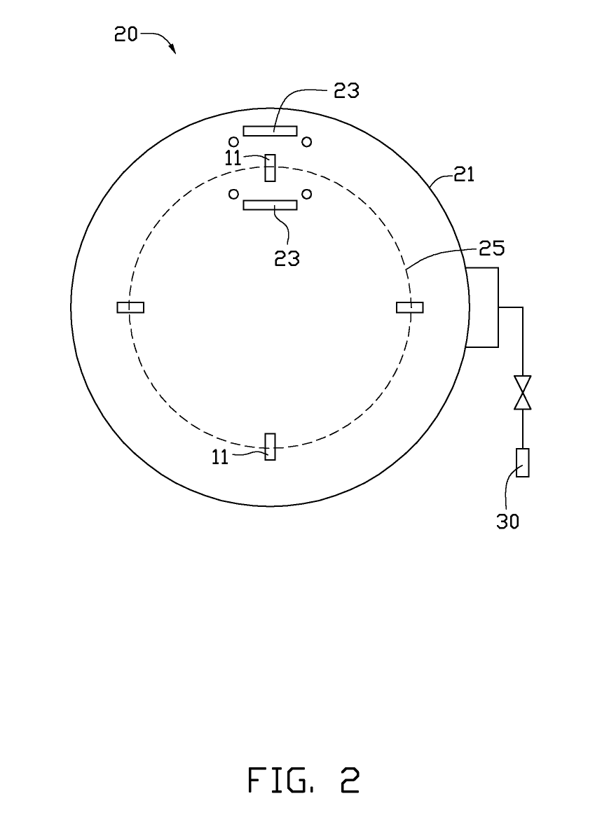

FIG. 2 shows a vacuum sputtering device 20, which includes a vacuum chamber 21 and a vacuum pump 30 connected to the vacuum chamber 21. The vacuum pump 30 is used for evacuating the air from the vacuum chamber 21. The vacuum chamber 21 has aluminum targets 23 and a rotary rack (not shown) positioned therein. The rotary rack holding the substrate 11 revolves along a circular path 25, and the substrate 11 is also rotated about its own axis while being held by the rotary rack.

A method for making the coated article 10 may include the following steps:

The substrate 11 is pretreated. The pre-treating process may include the following steps: electrolytic polishing the substrate 11; wiping the surface of the substrate 11 with deionized water and alcohol; ultrasonically cleaning the substrate 11 with acetone solution in an ultrasonic cleaner (not shown), to remove impurities such as grease or dirt from the substrate 11. Then, the substrate 11 is dried.

The substrate 11 is positioned in the rotary rack of the vacuum chamber 21 to be plasma cleaned. The vacuum chamber 21 is then evacuated to about 8.0×10⁻³ Pa. Argon gas (abbreviated as Ar, having a purity of about 99.999%) is used as the sputtering gas and is fed into the vacuum chamber 21 at a flow rate of about 300 standard-state cubic centimeters per minute (sccm) to about 500 sccm. A negative bias voltage in a range from about −300 volts (V) to about −750 V is applied to the substrate 11. The plasma then strikes the surface of the substrate 11 to clean the surface of the substrate 11. The plasma cleaning of the substrate 11 takes about 3 minutes (min) to about 10 min. The plasma cleaning process enhances the bond between the substrate 11 and the color layer 13.

The aluminum layer 131 is vacuum sputtered on the plasma cleaned substrate 11. Vacuum sputtering of the aluminum layer 131 is carried out in the vacuum chamber 21. The vacuum chamber 21 is heated to a temperature of about 100° C. to about 150° C. Ar is used as the sputtering gas and is fed into the vacuum chamber 21 at a flow rate of about 100 sccm to about 300 sccm. The aluminum targets 23 are supplied with electrical power of about 8 kw to about 13 kw. A negative bias voltage of about −50 V to about −200 V is applied to the substrate 11 and the duty cycle is from about 30% to about 75%. Deposition of the aluminum layer 131 takes about 10 min to about 30 min.

The aluminum oxide layer 133 is vacuum sputtered on the aluminum layer 131. Vacuum sputtering of the aluminum oxide layer 133 is carried out in the vacuum chamber 21. Oxygen (O₂) is used as the reaction gas and is fed into the vacuum chamber 21 at a flow rate of about 150 sccm to about 200 sccm. A negative bias voltage of about −50 V to about −100 V is applied to the substrate 11 and the duty cycle is from about 30% to about 50%. The flow rate of Ar and temperature of the vacuum chamber 21 are the same as vacuum sputtering of the aluminum layer 131. Deposition of the aluminum oxide layer 133 takes about 30 min to about 60 min.

### EXAMPLES

Experimental examples of the present disclosure are described as followings.

### Example 1

The plasma cleaning of the substrate 11 took place, wherein Ar was fed into the vacuum chamber 21 at a flow rate of about 300 sccm, a negative bias voltage of about −300 V was applied to the substrate 11. The plasma cleaning of the substrate 11 took about 10 min.

Sputterring to form the aluminum layer 131 took place, wherein the vacuum chamber 21 was heated to a temperature of about 120° C. . Ar was fed into the vacuum chamber 21 at a flow rate of about 150 sccm. The aluminum targets 23 were supplied with a power of about 10 kw, and a negative bias voltage of about −200 V was applied to the substrate 11. Deposition of the aluminum layer 131 took about 10 min.

Sputterring to form the aluminum oxide layer 133 took place, wherein oxygen was fed into the vacuum chamber 21 at a flow rate of about 150 sccm. Ar was fed into the vacuum chamber 21 at a flow rate of about 150 sccm. The aluminum targets 23 were supplied with a power of about 10 kw, and a negative bias voltage of about −100 V was applied to the substrate 11. Deposition of the aluminum layer 131 took about 60 min.

### Example 2

The vacuum sputtering device 20 in example 2 was the same in example 1.

The plasma cleaning of the substrate 11 took place, wherein Ar was fed into the vacuum chamber 21 at a flow rate of about 300 sccm, a negative bias voltage of about −300 V was applied to the substrate 11. The plasma cleaning of the substrate 11 took about 10 min.

Sputterring to form the aluminum layer 131 took place, wherein the vacuum chamber 21 was heated to a temperature of about 120° C. Ar was fed into the vacuum chamber 21 at a flow rate of about 150 sccm. The aluminum targets 23 were supplied with a power of about 10 kw, and a negative bias voltage of about −200 V was applied to the substrate 11. Deposition of the aluminum layer 131 took about 20 min.

Sputterring to form the aluminum oxide layer 133 took place, wherein oxygen was fed into the vacuum chamber 21 at a flow rate of about 170 sccm. Ar was fed into the vacuum chamber 21 at a flow rate of about 150 sccm. The aluminum targets 23 were supplied with a power of about 10 kw, and a negative bias voltage of about −100 V was applied to the substrate 11. Deposition of the aluminum layer 131 took about 60 min.

### Example 3

The vacuum sputtering device 20 in example 3 was the same in example 1.

The plasma cleaning of the substrate 11 took place, wherein Ar was fed into the vacuum chamber 21 at a flow rate of about 300 sccm, a negative bias voltage of about −300 V was applied to the substrate 11. The plasma cleaning of the substrate 11 took about 10 min.

Sputterring to form the aluminum layer 131 took place, wherein the vacuum chamber 21 was heated to a temperature of about 120° C. Ar was fed into the vacuum chamber 21 at a flow rate of about 150 sccm. The aluminum targets 23 were supplied with a power of about 10 kw, and a negative bias voltage of about −200 V were applied to the substrate 11. Deposition of the aluminum layer 131 took about 30 min.

Sputterring to form the aluminum oxide layer 133 took place, wherein oxygen was fed into the vacuum chamber 21 at a flow rate of about 200 sccm. Ar was fed into the vacuum chamber 21 at a flow rate of about 150 sccm. The aluminum targets 23 were supplied with a power of about 10 kw, and a negative bias voltage of about −100 V was applied to the substrate 11. Deposition of the aluminum layer 131 took about 60 min.

The color layer 13 includes the aluminum layer 131 and the aluminum oxide layer 133. The aluminum layer 131 has light white color and the aluminum oxide layer 133 presents a translucent effect, thus the color layer 13 presents a white color and gives the coated article 10 a white color appearance. The aluminum oxide layer 133 has a good wear resistance and can give the coated article 10 a long lasting pleasing appearance.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A coated article, comprising:
a aluminum or aluminum alloy substrate; and
a color layer formed on the aluminum or aluminum alloy substrate, the color layer including an aluminum layer formed on the aluminum or aluminum alloy substrate and an aluminum oxide layer formed on the aluminum layer; the color layer having a white color and in the CIE LAB color system, L* coordinate of the color layer being between 75 and 100, a* coordinate of the color layer being between −1 and 1, b* coordinate of the color layer being between −1 and 1.

2. The coated article as claimed in claim 1, wherein the aluminum layer has a thickness of about 1.0 μm to about 3.0 μm.

3. The coated article as claimed in claim 1, wherein the aluminum oxide layer has a thickness of about 0.5 μm to about 1.0 μm.

4. The coated article as claimed in claim 1, wherein the color layer is made by magnetron sputtering process.

5. A method for making a coated article, comprising:
providing a aluminum or aluminum alloy substrate; and
magnetron sputtering a color layer on the aluminum or aluminum alloy substrate, the color layer including an aluminum layer formed on the aluminum or aluminum alloy substrate and an aluminum oxide layer formed on the aluminum layer; the color layer having a white color and in the CIE LAB color system, L* coordinate of the color layer being between 75 and 100, a* coordinate of the color layer being between −1 and 1, b* coordinate of the color layer being between −1 and 1.

6. The method as claimed in claim 5, wherein magnetron sputtering the aluminum layer uses argon gas as the sputtering gas and argon gas has a flow rate of about 100 sccm to about 300 sccm; magnetron sputtering the aluminum layer is carried out at a temperature of about 100° C. to about 150° C.; uses aluminum targets and the aluminum targets are supplied with a power of about 8 kw to about 13 kw; a negative bias voltage of about −50 V to about −200 V is applied to the aluminum or aluminum alloy substrate and the duty cycle is from about 30% to about 75%.

7. The method as claimed in claim 6, wherein vacuum sputtering the aluminum layer takes about 10 min to about 30 min.

8. The method as claimed in claim 5, wherein magnetron sputtering the aluminum oxide layer uses oxygen as the reaction gas and oxygen has a flow rate of about 150 sccm to about 200 sccm; argon gas as the sputtering gas and argon gas has a flow rate of about 100 sccm to about 200 sccm; magnetron sputtering the aluminum oxide layer is carried out at a temperature of about 100° C. to about 150° C.; uses aluminum targets and the aluminum targets are supplied with a power of about 8 kw to about 13 kw; a negative bias voltage of about −50 V to about −100 V is applied to the aluminum or aluminum alloy substrate and the duty cycle is from about 30% to about 50%.

9. The method as claimed in claim 8, wherein vacuum sputtering the aluminum oxide layer takes about 30 min to about 60 min.
